(19) United States
(12) Patent Application Publication
(10) Pub. No.: US 2012/0037985 A1
(43) Pub. Date: Feb. 16, 2012

(54) APPARATUS WITH CAPACITIVE COUPLING AND ASSOCIATED METHODS

(76) Inventor: Michael Smith, Boise, ID (US)

(21) Appl. No.: 12/857,277

(22) Filed: Aug. 16, 2010

(51) Int. Cl. H01L 29/78; H01L 21/326

(52) U.S. Cl. 257/336; 438/468; 257/E29.256; 257/E21.327

(57) ABSTRACT

Transistors are described, along with methods and systems that include them. In one such transistor, a field plate is capacitively coupled between a first terminal and a second terminal. A potential in the field plate modulates dopant in a diffusion region in a semiconductor material of the transistor. Additional embodiments are also described.

### BACKGROUND

Field effect transistors are widely used in many electronic devices such as personal digital assistants (PDAs), laptop computers, mobile phones and digital cameras.

### BRIEF DESCRIPTION OF THE DRAWINGS

Some embodiments are illustrated by way of example and not limitation in the figures of the accompanying drawings in which:

FIG. 1 is a cross-sectional view of a field-effect transistor (FET) according to various embodiments of the invention;

FIG. 2 is a cross-sectional view of a portion of the FET shown in FIG. 1 according to various embodiments of the invention;

FIG. 3 is a top view of a FET according to various embodiments of the invention;

FIG. 4 is a top view of a FET according to various embodiments of the invention;

FIG. 5 is a top view of a FET according to various embodiments of the invention;

FIG. 6 is a top view of a FET according to various embodiments of the invention;

FIG. 7 is a cross-sectional view of a FET according to various embodiments of the invention;

FIG. 8 is a flow diagram of methods according to various embodiments of the invention; and

FIG. 9 is a diagram illustrating a system according to various embodiments of the invention.

### DETAILED DESCRIPTION

In the following description, for purposes of explanation, numerous examples having example-specific details are set forth to provide an understanding of example embodiments. Thus, the examples are set forth by way of explanation, and not limitation, so that various embodiments of the invention may include larger or smaller numbers of features than what may be included in any particular example embodiment.

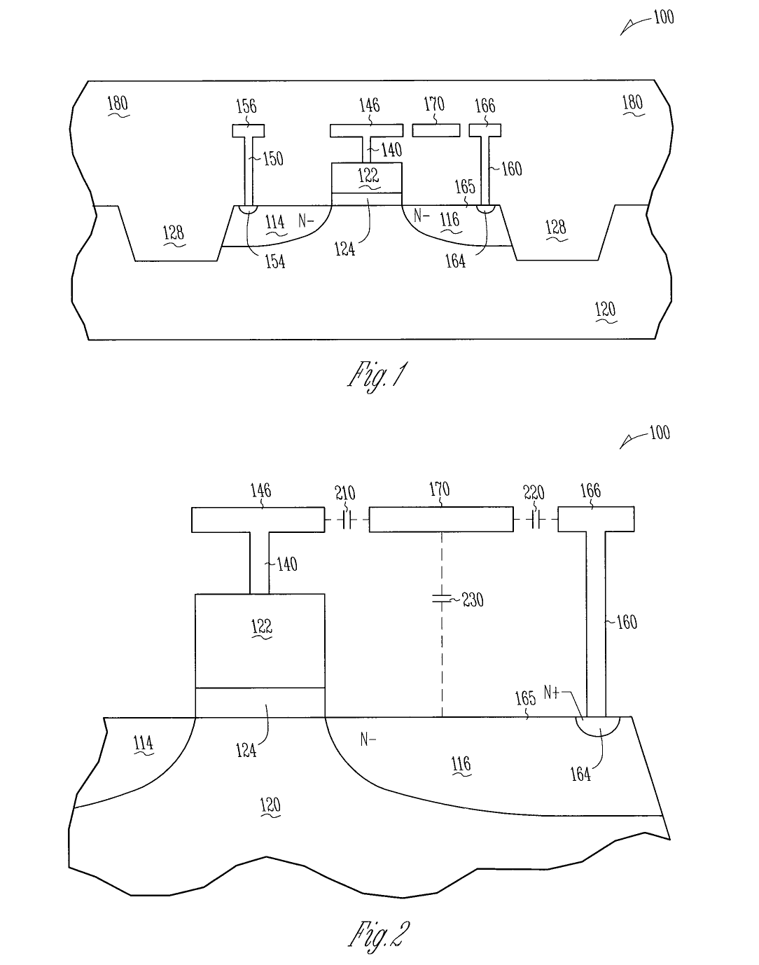

FIG. 1 is a cross-sectional view of a field-effect transistor (FET) 100 according to various embodiments of the invention. An N− type source diffusion region 114 and an N− type drain diffusion region 116 are formed in a P type semiconductor material, such as silicon substrate 120. A polysilicon gate electrode 122 is formed over a gate dielectric 124 which is formed over the silicon substrate 120 between the source diffusion region 114 and the drain diffusion region 116. The gate dielectric 124 may comprise, for example, silicon dioxide (SiO₍₂₎), oxynitride or nitrided oxide, according to various embodiments of the invention. A trench 128 in the silicon substrate 120 surrounds an active area of the FET 100. The source diffusion region 114 and the drain diffusion region 116 are formed in the silicon substrate 120 inside the trench 128.

The FET 100 may comprise a P channel FET with a P− type source diffusion region and a P− type drain diffusion region formed in an N type silicon substrate according to some embodiments of the invention. The gate electrode 122 may comprise metal rather than polysilicon according to some embodiments of the invention.

The gate electrode 122 is connected to a gate terminal 140 that includes a gate terminal head 146. A source terminal 150 is connected to a first N+ type contact diffusion region 154 inside the source diffusion region 114. The source terminal 150 includes a source terminal head 156. A drain terminal 160 is connected to a second N+ type contact diffusion region 164 inside the drain diffusion region 116. The portion of the drain diffusion region 116 between the gate dielectric 124 and the contact diffusion region 164 may be called a drain extension region 165.

The drain terminal 160 includes a drain terminal head 166. Each of the source terminal 150 and the drain terminal 160 is an elongated structure extending from the silicon substrate 120. The gate terminal 140 is an elongated structure extending from the gate electrode 122. The gate terminal head 146, the source terminal head 156, and the drain terminal head 166 extend laterally from the respective terminal 140, 150 and 160.

A field plate 170 is located between the gate terminal head 146 and the drain terminal head 166 over the drain diffusion region 116. The field plate 170 is capacitively coupled between the gate terminal head 146 and the drain terminal head 166.

The FET 100 is covered by a dielectric 180 that extends into the trench 128 and surrounds the terminals 140, 150 and 160, the terminal heads 146, 156 and 166 and the field plate 170. The field plate 170 is floating (e.g., it is electrically isolated by the dielectric 180). The dielectric 180 may comprise, for example, silicon dioxide, silicon oxide, silica or Borophosphosilicate glass (BPSG) according to various embodiments of the invention.

The terminals 140, 150 and 160, the terminal heads 146, 156 and 166, and the field plate 170 may comprise metal. The terminals 140, 150 and 160, the terminal heads 146, 156 and 166, and the field plate 170 may also comprise, for example, aluminum, copper, tungsten or polysilicon according to various embodiments of the invention.

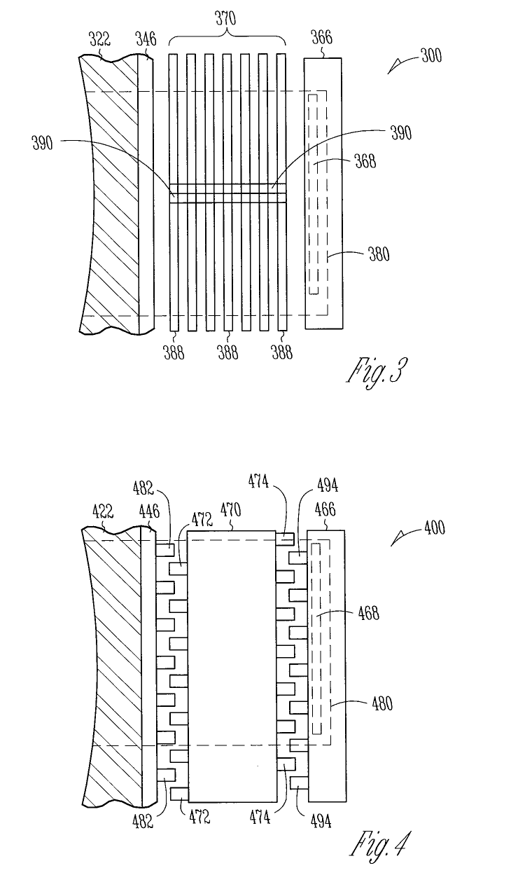

FIG. 2 is a cross-sectional view of a portion of the FET 100 shown in FIG. 1 according to various embodiments of the invention. Capacitive coupling between the field plate 170 and the gate terminal head 146 is represented by the capacitance 210. Capacitive coupling between the field plate 170 and the drain terminal head 166 is represented by the capacitance 220. The field plate 170 is sufficiently close to the silicon substrate 120 that a capacitive coupling exists between the field plate 170 and the drain diffusion region 116, represented by the capacitance 230. As an example, the field plate 170 may be approximately 5000 Angstroms from the silicon substrate 120. The amount of capacitive coupling represented by the capacitance 230 may be 8 nanofarads per square centimeter at this distance according to some embodiments of the invention. The field plate 170 may also be approximately 3000 Angstroms from the silicon substrate 120 according to some embodiments of the invention. The amount of capacitive coupling represented by the capacitances 210 and 220 depends on the distances between the field plate 170 and the respective terminal heads 146 and 166. The capacitances 210 and 220 also depend on a linear interface distance between the field plate 170 and the respective terminal heads 146 and 166 that is described below. The capacitances 210 and 220 may be, for example, 0.23 picofarads per centimeter where a distance between the field plate 170 and the respective terminal head 146 or 166 is 0.1 micrometers and the field plate 170 is metal and 700 Angstroms thick. A potential on the field plate 170 modulates dopant in the drain extension region 165 of the drain diffusion region 116 through the capacitance 230 under a drain breakdown voltage (Bvdss) bias condition in the FET 100.

The Bvdss bias condition occurs when there is a sufficient difference between the potential on the gate terminal 140 and the potential on the drain terminal 160 in the FET 100. In a high voltage FET, for example, the Bvdss bias condition occurs when the gate is at approximately 0 volts and the drain is at approximately 30 volts. The Bvdss voltage may be sensitive to the doping level in the drain extension region 165 of the drain diffusion region 116, and may exhibit a maximum value at a particular doping level. The doping level in the drain extension region 165 of the drain diffusion region 116 may result in the presence of a maximum Bvdss voltage for each FET in a system having multiple FETs according to various embodiments of the invention. The doping level at which the maximum Bvdss voltage occurs varies with other parameters, such as, for example, the width of the FET 100 and the presence of other implants in the drain diffusion region 116.

In a system having multiple FETs, each FET may have a unique Bvdss voltage based on its geometry, its doping level and other implants it received. The Bvdss voltage may exceed a minimum voltage for each FET according to various embodiments of the invention. According to some embodiments of the invention, each FET in a system has a similar maximum Bvdss voltage and the FETs are manufactured to be as small as possible. The inventors have discovered that these challenges, as well as others, can be addressed by including one or more field plates in each FET, such as the field plate 170 shown in FIG. 1. The field plate 170 is sufficiently close to the silicon substrate 120 to deplete or accumulate dopant in the drain extension region 165 of the drain diffusion region 116 through the capacitance 230 when there is a potential difference between the drain diffusion region 116 and the gate electrode 122. For example, the depletion or accumulation of dopant changes the maximum Bvdss voltage for the FET. A potential on the field plate 170 in the Bvdss bias condition determines a magnitude of the depletion or accumulation of dopant in the drain extension region 165 of the drain diffusion region 116.

As described above, the field plate 170 is floating and capacitively coupled between the gate terminal head 146 and the drain terminal head 166. The Bvdss bias condition occurs when the potential of the gate terminal head 146 is low and the potential of the drain terminal head 166 is high. According to the example cited above, the potential of the gate terminal head 146 is approximately 0 volts and the potential of the drain terminal head 166 is approximately 30 volts at the Bvdss bias condition. The potentials of the terminal heads 146 and 166 induce a potential on the field plate 170. The potential on the field plate 170 during the existence of the Bvdss bias condition is between the potentials of the terminal heads 146 and 166 and is determined by a ratio of the capacitances 210 and 220. Each FET in a system may have a field plate 170 with a different geometry, such that the Bvdss voltage is modified differently for each FET. The field plates may be designed such that different FETs in a system have the same Bvdss voltage during the Bvdss bias condition.

The capacitances 210 and 220 are determined by several factors such as, for example, the distance between the field plate 170 and the respective terminal head 146 and 166. Another factor is the linear interface distance between the field plate 170 and the respective terminal head 146 and 166. The linear interface distance is the length of the edge of the field plate 170 and the length of the edge of the gate terminal head 146 or the length of the edge of the drain terminal head 166 opposing the field plate 170. Irregular edges result in a greater linear interface distance than substantially straight edges. The ratio of the capacitances 210 and 220 can be modified by adjusting these factors. For example, to increase the capacitance 210 or capacitance 220, the field plate 170 can be brought closer to one of the terminal heads 146 or 166, respectively. The linear interface distance of an interface between the terminal head 146 or 166 and the field plate 170 can also be increased by an irregular edge to increase capacitance.

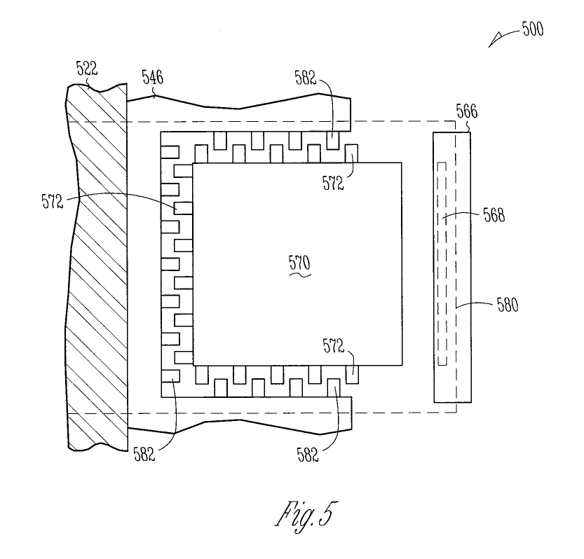

FIG. 3 is a top view of a FET 300 according to various embodiments of the invention. The FET 300 includes a polysilicon gate electrode 322 coupled to a gate terminal head 346. A drain terminal head 366 includes a number of contacts 368. A field plate 370 is located between the gate terminal head 346 and the drain terminal head 366. The field plate 370 is surrounded by a dielectric and is floating. An active area in a substrate (not shown) beneath the terminal heads 346 and 366 and the field plate 370 is indicated by a line 380. The contacts 368 provide a conductive path between the drain terminal head 366 and the substrate. The contacts 368 may comprise a continuous rectangular contact or a series of rounded contacts. The FET 300 includes other elements analogous to the elements of the FET 100 shown in FIG. 1 that are not shown or discussed for purposes of brevity and clarity.

The field plate 370 is made up of individual lines 388 of metal that are connected together by crossbeams 390 of metal. The lines 388 have a length, a width and a thickness that determine a capacitance of the field plate 370. The field plate 370 is substantially rectangular with straight edges and the terminal heads 346 and 366 also have substantially straight edges. As a result, capacitive coupling between the field plate 370 and the gate terminal head 346 may be substantially similar to a capacitive coupling between the field plate 370 and the drain terminal head 366. A potential on the field plate 370 may be approximately midway between a potential on the gate terminal head 346 and a potential on the drain terminal head 366 during the existence of a Bvdss bias condition.

The field plate 370 may comprise a single block of metal according to various embodiments of the invention. The terminal heads 346 and 366 may comprise metal. The terminal heads 346 and 366 and the field plate 370 may also comprise, for example, aluminum, copper, tungsten, or polysilicon according to various embodiments of the invention.

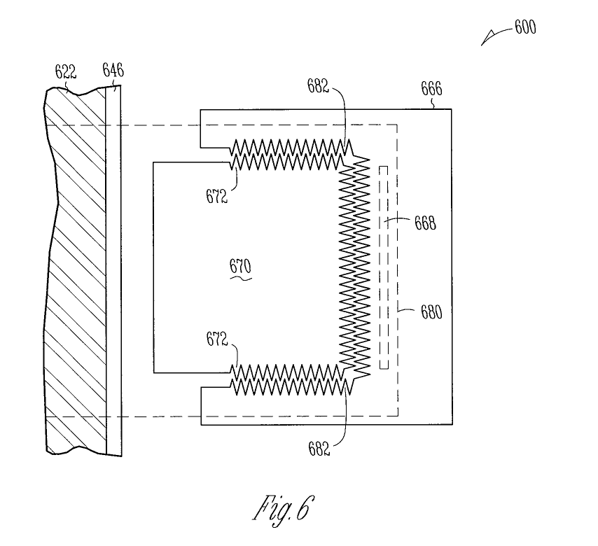

FIG. 4 is a top view of a FET 400 according to various embodiments of the invention. The FET 400 includes a polysilicon gate electrode 422 coupled to a gate terminal head 446. A drain terminal head 466 includes a number of contacts 468. A field plate 470 is located between the gate terminal head 446 and the drain terminal head 466. The field plate 470 is surrounded by a dielectric and is floating. An active area in a substrate (not shown) beneath the terminal heads 446 and 466 and the field plate 470 is indicated by a line 480. The contacts 468 provide a conductive path between the drain terminal head 466 and the substrate. The contacts 468 may comprise a continuous rectangular contact or a series of rounded contacts. The FET 400 includes other elements analogous to the elements of the FET 100 shown in FIG. 1 that are not shown or discussed for purposes of brevity and clarity.

The field plate 470 is a substantially rectangular block of metal having an irregular edge adjacent to the gate terminal head 446 and an irregular edge adjacent to the drain terminal head 466. The terminal heads 446 and 466 also have irregular edges that engage with the irregular edges of the field plate 470. The irregular edges of the field plate 470 and the gate terminal head 446 increase a linear interface distance between the two and increase the capacitive coupling therebetween. Similarly, the irregular edges of the field plate 470 and the drain terminal head 466 increase a linear interface distance between the two and increase the capacitive coupling therebetween. More specifically, the field plate 470 includes metal fingers 472 and 474 extending from its edges toward the terminal heads 446 and 466. The gate terminal head 446 includes metal fingers 482 that are interdigitally arranged with the metal fingers 472 extending from the field plate 470. Likewise, the drain terminal head 466 includes metal fingers 494 that are interdigitally arranged with the metal fingers 474 extending from the field plate 470.

The capacitive coupling between the field plate 470 and the gate terminal head 446 may be substantially similar to the capacitive coupling between the field plate 470 and the drain terminal head 466. A potential on the field plate 470 may be approximately midway between a potential on the gate terminal head 446 and a potential on the drain terminal head 466 during the Bvdss bias condition.

The terminal heads 446 and 466 may comprise metal. The terminal heads 446 and 466 and the field plate 470 may also comprise, for example, aluminum, copper, tungsten or polysilicon according to various embodiments of the invention.

FIG. 5 is a top view of a FET 500 according to various embodiments of the invention. The FET 500 includes a polysilicon gate electrode 522 coupled to a gate terminal head 546. A drain terminal head 566 includes a number of contacts 568. A field plate 570 is located between the gate terminal head 546 and the drain terminal head 566. The field plate 570 is surrounded by a dielectric and is floating. An active area in a substrate (not shown) beneath the terminal heads 546 and 566 and the field plate 570 is indicated by a line 580. The contacts 568 provide a conductive path between the drain terminal head 566 and the substrate. The contacts 568 may comprise a continuous rectangular contact or a series of rounded contacts. The FET 500 includes other elements analogous to the elements of the FET 100 shown in FIG. 1 that are not shown or discussed for purposes of brevity and clarity.

The field plate 570 is a substantially rectangular block of metal having three irregular edges adjacent to and facing the gate terminal head 546. The gate terminal head 546 is U-shaped having three edges that partially surround the field plate 570. The three edges of the gate terminal head 546 that face the field plate 570 are also irregular and engage with the irregular edges of the field plate 570. The irregular edges of the field plate 570 include, for example, metal fingers 572 extending toward the gate terminal head 546. The gate terminal head 546 also includes metal fingers 582 extending from the three edges that face the field plate 570. The metal fingers 582 are interdigitally arranged with the metal fingers 572 extending from the field plate 570. The field plate 570 has a substantially straight edge that faces a substantially straight edge of the drain terminal head 566.

The irregular edges of the field plate 570 and the gate terminal head 546 increase a linear interface distance between the field plate 570 and the gate terminal head 546 and thus, increase the capacitive coupling therebetween. Therefore, the capacitive coupling between the field plate 570 and the gate terminal head 546 is greater than the capacitive coupling between the field plate 570 and the drain terminal head 566. A potential on the field plate 570 will be closer to a potential on the gate terminal head 546 that to a potential on the drain terminal head 566 during the Bvdss bias condition.

The terminal heads 546 and 566 may comprise metal. The terminal heads 546 and 566 and the field plate 570 may also comprise, for example, aluminum, copper, tungsten or polysilicon according to various embodiments of the invention.

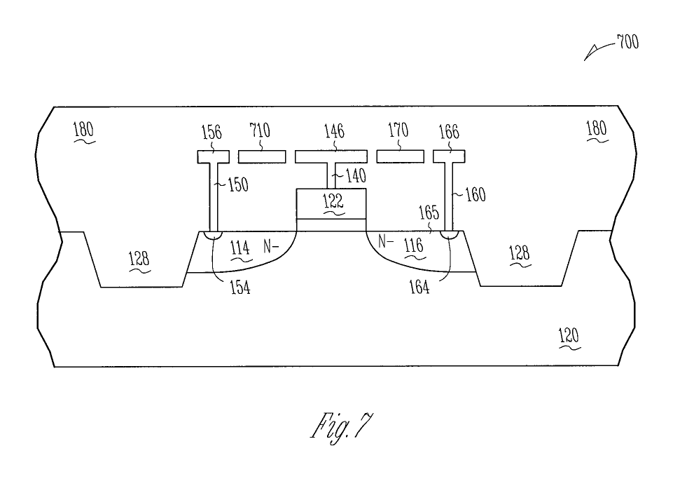

FIG. 6 is a top view of a FET 600 according to various embodiments of the invention. The FET 600 includes a polysilicon gate electrode 622 coupled to a gate terminal head 646. A drain terminal head 666 includes a number of contacts 668. A field plate 670 is located between the gate terminal head 646 and the drain terminal head 666. The field plate 670 is surrounded by a dielectric and is floating. An active area in a substrate (not shown) beneath the terminal heads 646 and 666 and the field plate 670 is indicated by a line 680. The contacts 668 provide a conductive path between the drain terminal head 666 and the substrate. The contacts 668 may comprise a continuous rectangular contact or a series of rounded contacts. The FET 600 includes other elements analogous to the elements of the FET 100 shown in FIG. 1 that are not shown or discussed for purposes of brevity and clarity.

The field plate 670 is a substantially rectangular block of metal having three irregular edges adjacent to and facing the drain terminal head 666. The drain terminal head 666 is U-shaped having three edges that partially surround the field plate 670. The three edges of the drain terminal head 666 that face the field plate 670 are also irregular and engage with the irregular edges of the field plate 670. The irregular edges of the field plate 670 include, for example, a sawtooth pattern 672 extending toward the drain terminal head 666. The drain terminal head 666 also includes a sawtooth pattern 682 extending from the three edges that face the field plate 670. The sawtooth pattern 682 is interdigitally arranged with the sawtooth pattern 672 extending from the field plate 670. The field plate 670 has a substantially straight edge that opposes a substantially straight edge of the gate terminal head 646.

The irregular edges of the field plate 670 and the drain terminal head 666 increase a linear interface distance between the field plate 670 and the drain terminal head 666 and thus, increase the capacitive coupling therebetween. Therefore, the capacitive coupling between the field plate 670 and the drain terminal head 666 is greater than the capacitive coupling between the field plate 670 and the gate terminal head 646. A potential on the field plate 670 will be closer to a potential on the drain terminal head 666 that to a potential on the gate terminal head 646 during the Bvdss bias condition.

The terminal heads 646 and 666 may comprise metal. The terminal heads 646 and 666 and the field plate 670 may also comprise, for example, aluminum, copper, tungsten or polysilicon according to various embodiments of the invention.

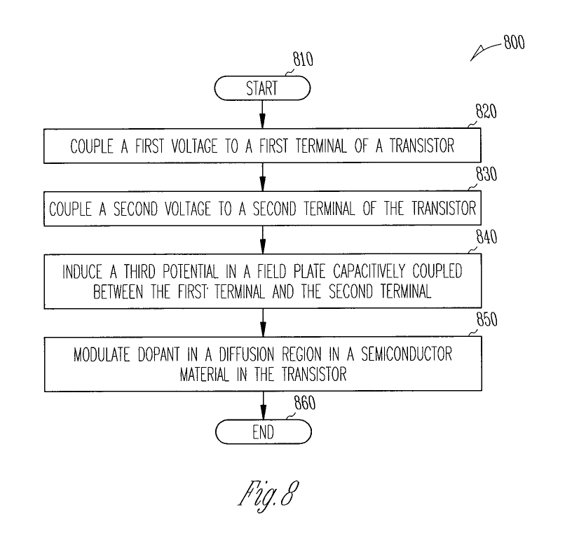

The FET 100 shown in FIG. 1 is asymmetrical because there is only one field plate 170 located between the gate terminal head 146 and the drain terminal head 166. The FET 100 may be asymmetrical for other reasons. For example, an implant in the source diffusion region 114 may be different from an implant in the drain diffusion region 116. The implants in the diffusion regions 114 and 116 may also be the same according to various embodiments of the invention. A substantially symmetrical FET 700 is shown in FIG. 7 according to various embodiments of the invention.

FIG. 7 is a cross-sectional view of a FET 700 according to various embodiments of the invention. The FET 700 includes elements similar to the elements of the FET 100 shown in FIG. 1, and the similar elements are given the same reference numerals in both FIG. 1 and FIG. 7 and will not be further described for purposes of brevity and clarity.

The FET 700 includes a field plate 710 located between the gate terminal head 146 and the source terminal head 156 over the source diffusion region 114. The field plate 710 is capacitively coupled between the heads 146 and 156. The dielectric 180 surrounds the field plate 710. The field plate 710 is sufficiently close to the silicon substrate 120 that a capacitive coupling exists between the field plate 710 and the source diffusion region 114. A potential on the field plate 710 modulates an effective doping level in the source diffusion region 114 through the capacitive coupling under the Bvdss bias condition in the FET 100. The field plate 710 may comprise metal. The field plate 710 may also comprise, for example, aluminum, copper, tungsten or polysilicon according to various embodiments of the invention. The FET 700 has the field plates 170 and 710 on either side of the gate terminal head 146.

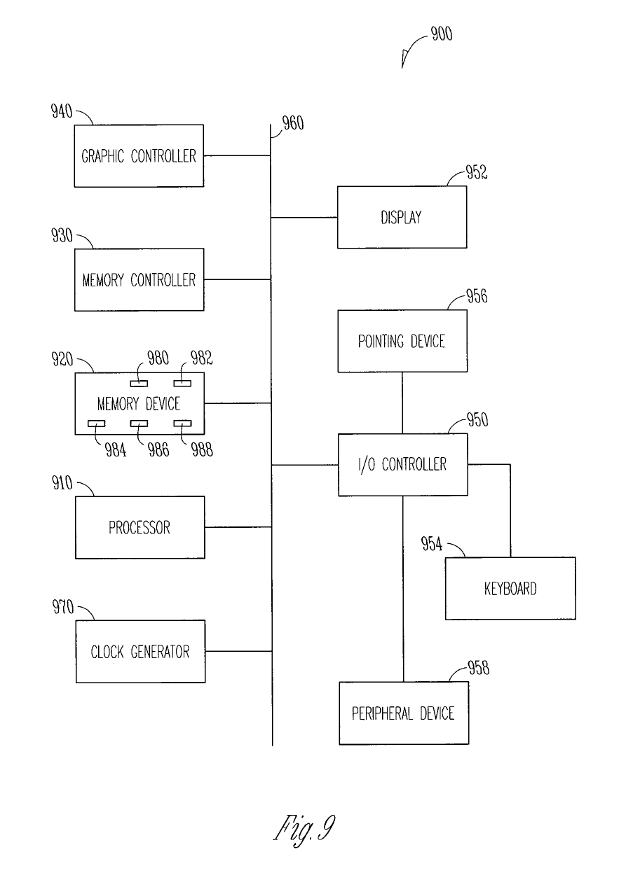

FIG. 8 is a flow diagram of methods 800 according to various embodiments of the invention. In block 810, the methods 800 start. In block 820, a first voltage is coupled to a first terminal of a transistor. In block 830, a second voltage is coupled to a second terminal of the transistor. In block 840, a third potential is induced in a field plate capacitively coupled between the first terminal and the second terminal. In block 850, dopant in a diffusion region in a semiconductor material in the transistor is modulated. In block 860, the methods 800 end. Various embodiments may have more or fewer activities than those shown in FIG. 8.

The various embodiments of the invention shown and described herein enable modulation of dopant in individual FETs under the existence of Bvdss conditions in a single device. The use of field plates simplifies the modulation mechanism, and may reduce the size of the resulting FETs, as compared with FETs that employ other ways of modulating dopant. The potential of the field plate under the Bvdss bias condition may be customized with a change in the dimensions or the location of the field plate, without using extra circuitry.

By changing the layout, a field plate can be added to a FET without changing the FET fabrication process. The field plate can be adjusted to accommodate process changes with a single mask alteration, in some cases.

In addition, the addition of a field plate to a FET usually does not require an increase in size, position, or the number of FETs in a single device. Thus, a field plate can often be retrofitted into existing circuitry without otherwise altering the layout or circuit design. The field plate can be customized for each FET, with adjustments being made for the dimensions or the location of the field plate.

FIG. 9 is a diagram illustrating a system 900 according to various embodiments of the invention. The system 900 may include a processor 910, a memory device 920, a memory controller 930, a graphic controller 940, an input and output (I/O) controller 950, a display 952, a keyboard 954, a pointing device 956, and a peripheral device 958. A bus 960 couples all of these devices together. A clock generator 970 is coupled to the bus 960 to provide a clock signal to at least one of the devices of the system 900 through the bus 960. The clock generator 970 may include an oscillator in a circuit board such as a motherboard. Two or more devices shown in system 900 may be formed in a single integrated circuit chip.

The bus 960 may include interconnect traces on a circuit board or may comprise one or more cables. The bus 960 may couple the devices of the system 900 by wireless means such as by electromagnetic radiations, for example, radio waves. The peripheral device 958 coupled to the I/O controller 950 may comprise a printer, an optical device such as a CD-ROM and a DVD reader and writer, a magnetic device reader and writer such as a floppy disk driver, or an audio device such as a microphone.

The memory device 920 includes several FETs 980, 982, 984, 986 and 988, which may be constructed according to the description of any one of the FETs shown and described herein, according to various embodiments of the invention. The FETs 980, 982, 984, 986 and 988 each have one or more field plates. Each of the field plates may have a unique geometry that is different from the geometries of other field plates according to various embodiments of the invention. The field plates may also have the same geometry. Other elements of the system 900 such as the processor 910, the memory controller 930, the graphic controller 940, the input and output (I/O) controller 950, the display 952, the keyboard 954, the pointing device 956, and the peripheral device 958 may include one or more FETs with field plates according to various embodiments of the invention.

The system 900 represented by FIG. 9 may include computers (e.g., desktops, laptops, hand-helds, servers, Web appliances, routers, etc.), wireless communication devices (e.g., cellular phones, cordless phones, pagers, personal digital assistants, etc.), computer-related peripherals (e.g., printers, scanners, monitors, etc.), entertainment devices (e.g., televisions, radios, stereos, tape and compact disc players, video cassette recorders, camcorders, digital cameras, MP3 (Motion Picture Experts Group, Audio Layer 3) players, video games, watches, etc.), and the like.

Any of the circuits or systems described herein may be referred to as a module. A module may comprise a circuit and/or firmware according to various embodiments.

Example FETs, systems, and methods have been described. Although several specific embodiments have been described, it will be evident that various modifications and changes may be made to these embodiments. Accordingly, the specification and drawings are to be regarded in an illustrative rather than a restrictive sense.

The Abstract of the Disclosure is provided to comply with 37 C.F.R. §1.72(b), requiring an abstract that allows the reader to quickly ascertain the nature of the technical disclosure. It is submitted with the understanding that it will not be used to interpret or limit the claims. In addition, in the foregoing Detailed Description, it may be seen that various features are grouped together in a single embodiment for the purpose of streamlining the disclosure. This method of disclosure is not to be interpreted as limiting the claims. Thus, the following claims are hereby incorporated into the Detailed Description, with each claim standing on its own as a separate embodiment.

What is claimed is:

1. A transistor comprising:
a first terminal;
a second terminal; and
a field plate capacitively coupled between the first terminal and the second terminal.

2. The transistor of claim 1, wherein the first terminal, the second terminal and the field plate each comprise metal.

3. The transistor of claim 1, wherein the first terminal, the second terminal and the field plate each include at least one of aluminum, copper, tungsten, or polysilicon.

4. The transistor of claim 1, wherein:
the first terminal is a gate terminal coupled to a gate over an active area in a semiconductor material; and
the second terminal is a drain terminal coupled to a diffusion region in the semiconductor material.

5. The transistor of claim 1, wherein:
the first terminal is a gate terminal coupled to a gate over an active area in a semiconductor material; and
the second terminal is a source terminal coupled to a diffusion region in the semiconductor material.

6. The transistor of claim 4, wherein the diffusion region comprises a drain extension region.

7. A transistor comprising:
a gate terminal coupled to a gate over an active area in a semiconductor material;
a drain terminal coupled to a first diffusion region in the semiconductor material;
a source terminal coupled to a second diffusion region in the semiconductor material; and
a field plate capacitively coupled between the gate terminal and the drain terminal.

8. The transistor of claim 7, wherein the first diffusion region comprises a drain extension region.

9. The transistor of claim 7, wherein:
each terminal has a head that extends laterally; and
the field plate is floating and capacitively coupled between the head of the gate terminal and the head of the drain terminal.

10. The transistor of claim 7, wherein the gate terminal is U-shaped and is adjacent to a plurality of sides of the field plate.

11. The transistor of claim 7, wherein the drain terminal is U-shaped and is adjacent to a plurality of sides of the field plate.

12. The transistor of claim 7, wherein:
edges of the field plate are irregular; and
edges of the drain terminal are irregular.

13. The transistor of claim 12, wherein the irregular edges of the field plate comprise a sawtooth pattern.

14. The transistor of claim 7, wherein:
edges of the field plate are irregular; and
edges of the gate terminal are irregular.

15. The transistor of claim 7, wherein:
edges of the field plate are irregular; and
edges of the source terminal are irregular.

16. The transistor of claim 7, wherein the field plate comprises individual lines connected together by crossbeams.

17. The transistor of claim 7, wherein the field plate is substantially rectangular.

18. The transistor of claim 17, wherein the field plate has straight edges and heads of the terminals have substantially straight edges.

19. The transistor of claim 7, wherein the field plate comprises a single block of metal.

20. The transistor of claim 19, wherein the block of metal has three irregular edges adjacent to and facing a head of the gate terminal.

21. The transistor of claim 7, wherein the field plate includes fingers extending from its edges towards heads of at least two of the terminals, and wherein the heads of the at least two of the terminals include fingers that are interdigitally arranged with the metal fingers extending from the field plate.

22. The transistor of claim 7, wherein the field plate has a substantially straight edge that faces a substantially straight edge of a head of the drain terminal.

23. The transistor of claim 22, further comprising another field plate capacitively coupled between the gate terminal and the source terminal.

24. A method comprising:
coupling a first voltage to a first terminal of a transistor; and
coupling a second voltage to a second terminal of the transistor, wherein a third potential is induced in a field plate capacitively coupled between the first terminal and the second terminal that modulates dopant in a diffusion region in a semiconductor material of the transistor.

25. The method of claim 24, wherein:
coupling a first voltage further comprises coupling a low voltage to a gate terminal of the transistor; and
coupling a second voltage further comprises coupling a high voltage that is higher than the low voltage to a drain terminal of the transistor.

26. The method of claim 25, wherein the low voltage is less than about one volt and the high voltage is greater than about 20 volts.

27. The method of claim 24, wherein the third potential is between the first voltage and the second voltage.

28. The method of claim 24, wherein the dopant in a drain extension region of the diffusion region is modulated.

29. A system comprising:
a plurality of transistors, each transistor comprising
a first terminal;
a second terminal; and
a field plate capacitively coupled between the first terminal and the second terminal, wherein at least one of the field plates in the plurality of transistors has a geometry that is different from geometries of the other field plates in the plurality of transistors.

30. The system of claim 29, wherein, for at least one of the plurality of transistors:
the field plate is capacitively coupled between a gate terminal and a drain terminal of the transistor; and
the field plate is located over a drain extension region in a semiconductor material of the transistor.

31. The system of claim 29, wherein, for at least one of the plurality of transistors:
an edge of the field plate is irregular; and
an edge of the first terminal is irregular, and the irregular edge of the first terminal faces the irregular edge of the field plate.
